(19) United States
(12) Patent Application Publication
(10) Pub. No.: US 2025/0233030 A1
(43) Pub. Date: Jul. 17, 2025

(54) SEMICONDUCTOR MODULE

(71) Applicant: SAMSUNG ELECTRONICS CO., LTD., Suwon-si (KR)

(72) Inventors: Hwanjoo Park, Suwon-si (KR); Byunghan Ko, Suwon-si (KR); Wook Moon, Suwon-si (KR); Heechul Lee, Suwon-si (KR)

(21) Appl. No.: 18/812,545

(22) Filed: Aug. 22, 2024

(30) Foreign Application Priority Data
Jan. 16, 2024 (KR) 10-2024-0006973

(51) Int. Cl. H01L 23/13; H01L 23/34; H01L 25/18; H05K 1/02; H10B 80/00

(52) U.S. Cl. CPC H01L 23/13; H01L 23/345; H01L 25/18; H05K 1/0201; H10B 80/00; H05K 2201/09063; H05K 2201/10159

(57) ABSTRACT

A semiconductor module includes a module substrate, a controller device and a memory device mounted on a surface of the module substrate, and a plurality of tabs at a side of the module substrate. The module substrate has a first through hole that vertically extends through the module substrate. The first through hole is between the controller device and the memory device. The first through hole extends in a first direction that runs across between the controller device and the memory device. A length along the first direction of the first through hole is less than a width along the first direction of the controller device.

### CROSS-REFERENCE TO RELATED APPLICATION

This U.S. nonprovisional application claims priority under 35 U.S.C. § 119 to Korean Patent Application No. 10-2024-0006973 filed on Jan. 16, 2024, in the Korean Intellectual Property Office, the disclosure of which is hereby incorporated by reference in its entirety.

### BACKGROUND

A circuit board is configured such that electronic devices are mounted on a dielectric substrate, and that the electronic devices are electrically connected to a conductive line that constitutes a circuit on the dielectric substrate. Externally received electric signals are transferred through the conductive line to corresponding electronic devices, and electric signals processed and outputted by the electronic devices are delivered through the conductive line to other electronic devices or outside. The circuit board uses electrical signals to drive the electronic devices or external components connected to the circuit board.

The electronic device radiates a certain amount of heat while driving. The heat radiated from the electronic devices is outwardly delivered in the form of radiant heat or conduction heat that is transmitted through the conductive line or the dielectric substrate. A semiconductor module has generally a thermal radiation means such as a thermal radiation plate for discharging heat generated during operations of the electromagnetic devices.

### SUMMARY

The present disclosures provide a semiconductor module with improved thermal stability.

According to some implementations a semiconductor module may comprise: a module substrate; a controller device and a memory device mounted on a surface of the module substrate; and a plurality of tabs at a side of the module substrate. The module substrate may have a first through hole that vertically extends through the module substrate. The first through hole may be between the controller device and the memory device. The first through hole may extend in a first direction that runs across between the controller device and the memory device. A length of the first through hole along the first direction may be less than a width of the controller device along the first direction.

According to some implementations, a semiconductor module may comprise: a module substrate; a controller device, a memory device, and a power device that are spaced apart from each other on a top surface of the module substrate; and a plurality of tabs on one side of the module substrate in a first direction. The controller device and the power device may be on one side of the memory device in the first direction. The module substrate may have a first through hole and a second through hole that vertically extend through the module substrate. The first through hole may extend in a second direction between the controller device and the memory device. The second direction may intersect the first direction. The second through hole may be between the controller device and the power device.

According to some implementations, a semiconductor module may comprise: a substrate; a first heating device mounted on a top surface of the substrate; and a second heating device mounted on the top surface of the substrate and spaced apart in a first direction from the first heating device. The substrate may have a through hole between the first heating device and the second heating device. The through hole may vertically extend through the substrate. The through hole may extend in a second direction that runs across between the first heating device and the second heating device. A length along the second direction of the through hole may be less than a width along the second direction of the first heating device and a width along the second direction of the second heating device. The through hole may be filled with air.

### BRIEF DESCRIPTION OF DRAWINGS

FIG. 1 illustrates a perspective view showing an example semiconductor module.

FIG. 2 illustrates a plan view showing an example semiconductor module.

FIG. 3 illustrates a cross-sectional view taken along line I-I′ of FIG. 2.

FIGS. 4 to 8 illustrate plan views showing an example semiconductor module.

FIG. 9 illustrates a cross-sectional view taken along line II-II′ of FIG. 8.

FIG. 10 illustrates a plan view showing an example semiconductor module.

FIG. 11 illustrates a cross-sectional view taken along line III-III′ of FIG. 10.

FIG. 12 illustrates a plan view showing an example semiconductor module.

FIG. 13 illustrates a cross-sectional view taken along line IV-IV′ of FIG. 12.

FIG. 14 illustrates a cross-sectional view showing an example semiconductor package.

### DETAILED DESCRIPTION

The following will now describe a semiconductor module according to implementations with reference to accompanying drawings.

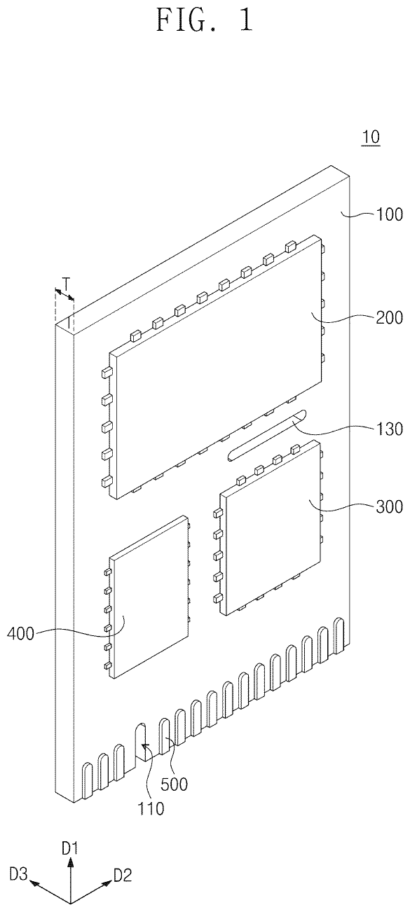

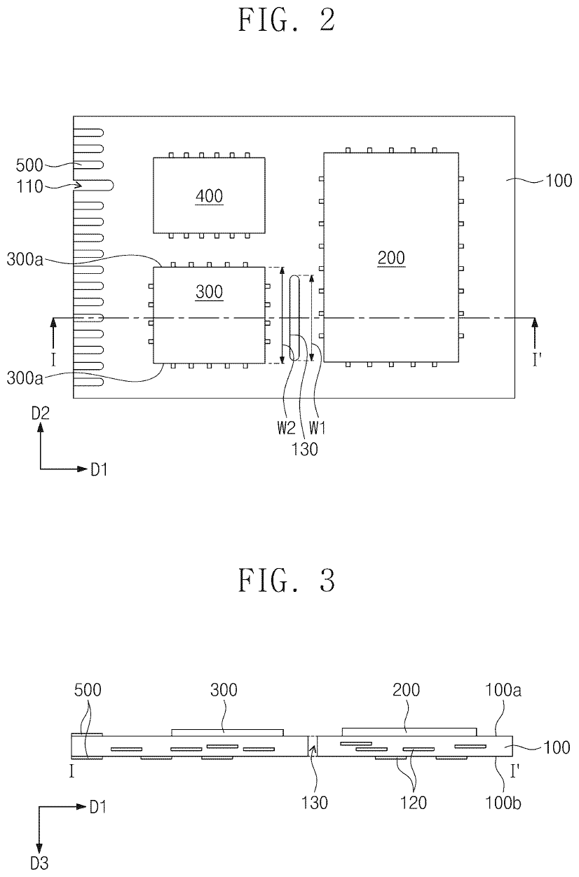

FIG. 1 illustrates a perspective view showing an example semiconductor module. FIG. 2 illustrates a plan view showing an example semiconductor module. FIG. 3 illustrates a cross-sectional view taken along line I-I′ of FIG. 2.

For convenience of description, a positional relation of a semiconductor module 10 will be described on the basis of three axes orthogonal to each other, for example, a first direction D1 and a second direction D2 parallel to one surface of a module substrate 100 and a third direction D3 perpendicular to the one surface of the module substrate 100. The first direction D1 may intersect the second direction D2.

Referring to FIGS. 1 to 3, the semiconductor module 10 may include the module substrate 100, a first heating device 200, a second heating device 300, a third heating device 400, and tabs 500.

The module substrate 100 may have a tetragonal plate shape, which may extend in the first direction D1. The module substrate 100 may have a first surface 100a and a second surface 100b that are opposite to each other. The module substrate 100 may have a substantially uniform thickness T. In this description, the thickness T of the module substrate 100 may indicate an interval between the first surface 100a and the second surface 100b. The module substrate 100 may include a printed circuit board (PCB). The module substrate 100 may have, at one side thereof, an insertion hole for alignment with or fixation to a motherboard socket of an electronic product such as a computer. The insertion hole 110 may be disposed adjacent to one lateral surface in a direction opposite to the first direction D1 of the module substrate 100.

A conductive line 120 may be provided on the module substrate 100. The conductive line 120 may be provided within the module substrate 100 or may be provided on either the first surface 100a or the second surface 100b of the module substrate 100. The conductive line 120 may electrically connect to each other the first heating device 200, the second heating device 300, the third heating device 400, and the tabs 500.

The first heating device 200 may be mounted on the first surface 100a of the module substrate 100. For example, the first heating device 200 may be mounted through wires or lead frames on the module substrate 100. Different from that shown, the first heating device 200 may be mounted on the second surface 100b of the module substrate 100. According to some embodiments, the first heating device 200 may be provided in plural. In this case, the plurality of first heating devices 200 may be mounted on only the first surface 100a of the module substrate 100, only the second surface 100b of the module substrate 100, or on both the first surface 100a and the second surface 100b of the module substrate 100. The plurality of first heating devices 200 may be spaced apart from each other. The following will focus on embodiments of FIGS. 1 to 3. The first heating device 200 may be electrically connected to the conductive line 120 of the module substrate 100. The first heating device 200 may emit a high thermal energy in the middle of its operating procedure. The first heating device 200 may include a memory device. For example, the first heating device 200 may include a NAND Flash memory. For another example, the first heating device 200 may include one of other memory devices such as DRAM, NOR Flash, OneNAND, PRAM, ReRAM, or MRAM.

The second heating device 300 may be mounted on one surface of the module substrate 100 on which surface the first heating device 200 is mounted. The second heating device 300 may be mounted on the first surface 100a of the module substrate 100. For example, the second heating device 300 may be mounted through wires or lead frames on the module substrate 100. Different from that shown, the second heating device 300 may be mounted on the second surface 100b of the module substrate 100. The second heating device 300 may be disposed on a central portion of the first surface 100a of the module substrate 100. When viewed in plan, the second heating device 300 may be disposed in a direction opposite to the first direction D1 from the first heating device 200. The second heating device 300 may be spaced apart from the first heating device 200. The present implementations, however, are not limited thereto, and the first heating device 200 and the second heating device 300 may be disposed in various ways. The second heating device 300 may be electrically connected to the first heating device 200 through the conductive line 120 of the module substrate 100. The second heating device 300 may emit a higher thermal energy in the middle of its operating procedure than that of the first heating device 200. For example, the second heating device 300 may include a controller device. The second heating device 300 may include a register clock driver (RCD), a photoelectronic device, a communication device, a digital signal processor, a controller, a system-on-chip, or any other logic device.

The third heating device 400 may be mounted on the module substrate 100. For example, the third heating device 400 may be mounted through wires or lead frames on the module substrate 100. Different from that shown, the third heating device 400 may be mounted on the second surface 100b of the module substrate 100. The third heating device 400 may be disposed on a central portion of the first surface 100a of the module substrate 100. When viewed in plan, the third heating device 400 may be disposed in a direction opposite to the first direction D1 from the first heating device 200. When viewed in plan, the third heating device 400 may be disposed in the second direction D2 of the second heating device 300. For example, the second heating device 300 and the third heating device 400 may be arranged in the second direction D2 on one side in a direction opposite to the first direction D1 of the first heating device 200. The third heating device 400 may be spaced apart from the first heating device 200 and the second heating device 300. The present embodiments, however, are not limited thereto, and the first heating device 200, the second heating device 300, and the third heating device 400 may be disposed in various ways. The third heating device 400 may be electrically connected to the first heating device 200 and the second heating device 300 through the conductive line 120 of the module substrate 100. The third heating device 400 may emit a high thermal energy in the middle of its operating procedure. The third heating device 400 may include, for example, a power device. The third heating device 400 may include a power device, such as a power management integrated circuit (PMIC).

The tabs 500 may be disposed at one end of the module substrate 100. For example, the tabs 500 may be disposed in a direction opposite to the first direction D1 from a center of the module substrate 100. The tabs 500 may be in contact with a lateral surface in a direction opposite to the first direction D1 of the module substrate 100. The tabs 500 may be arranged along the lateral surface in a direction opposite to the first direction D1 of the module substrate 100. For example, the tabs 500 may have a string array in which the tabs 500 are spaced apart from each other in the second direction D2. The tabs 500 may extend onto one of the first surface 100a and the second surface 100b of the module substrate 100. The insertion hole 110 may be positioned between the tabs 500. The tabs 500 may be electrically connected to the first heating device 200, the second heating device 300, and the third heating device 400. The tabs 500 may transmit electrical signals to the outside and receives electrical signals from the outside. For example, one side of each tab 500 may be inserted into a motherboard socket of an electronic product such as a computer to come into electrical connection with the electronic product. Another side of each tabs 500 may be electrically connected to the conductive line 120 of the module substrate 100. The tabs 500 may be directly coupled to the motherboard socket and directly or indirectly connected to the conductive line 120 of the module substrate 100.

A first through hole 130 may be provided in the module substrate 100. When viewed in plan, the first through hole 130 may be disposed between the first heating device 200 and the second heating device 300. The first through hole 130 may be spaced apart from the first heating device 200 and the second heating device 300. The first through hole 130 may completely extend in the third direction D3 through the module substrate 100. The first through hole 130 may run across between the first heating device 200 and the second heating device 300. For example, the first through hole 130 may have a linear shape that extends in the second direction D2.

According to some implementations the second heating device 300 may emit a thermal energy greater than that of the first heating device 200. The module substrate 100 may be provided with the first through hole 130 between the first heating device 200 and the second heating device 300. Thus, the first heating device 200 may be prevented from receiving heat emitted from the second heating device 300 and from being damaged by the heat. Thereby, the semiconductor module 10 may increase in thermal stability and operating stability.

When viewed in the first direction D1, the first through hole 130 may be positioned between lateral surfaces 300a in the second direction D2 of the second heating device 300. A length W1 along the second direction D2 of the first through hole 130 may be less than a width along the second direction D2 of the first heating device 200. The length W1 of the first through hole 130 may be less than a width W2 along the second direction D2 of the second heating device 300. The length W1 of the first through hole 130 may be about 0.2 times to about 1.0 times the width W2 of the second heating device 300. For example, the length W1 of the first through hole 130 may be about 0.4 times to about 0.8 times the width W2 of the second heating device 300. When the length W1 of the first through hole 130 is less than about 0.2 times the width W2 of the second heating device 300, it may not be possible to effectively block heat transferred from the second heating device 300 to the first heating device 200. When the length W1 of the first through hole 130 is greater than about 1.0 times the width W2 of the second heating device 300, it may be possible to excessively block heat discharged in the first direction D1 from the second heating device 300. Therefore, the heat may be accumulated in the second heating device 300, and the second heating device 300 may be damaged by the heat.

The first through hole 130 may have a width in the first direction D1, which width may be similar to the thickness T of the module substrate 100. Alternatively, the width of the first through hole 130 may be greater than the thickness T of the module substrate 100. The first through hole 130 may have an empty inside. For example, the inside of the first through hole 130 may be filled with air.

In the embodiments that follow, a detailed description of technical features repetitive to those discussed above with reference to FIGS. 1 to 3 will be omitted, and a difference thereof will be discussed in detail. The same reference numerals may be allocated to the same components as those of the semiconductor module discussed above.

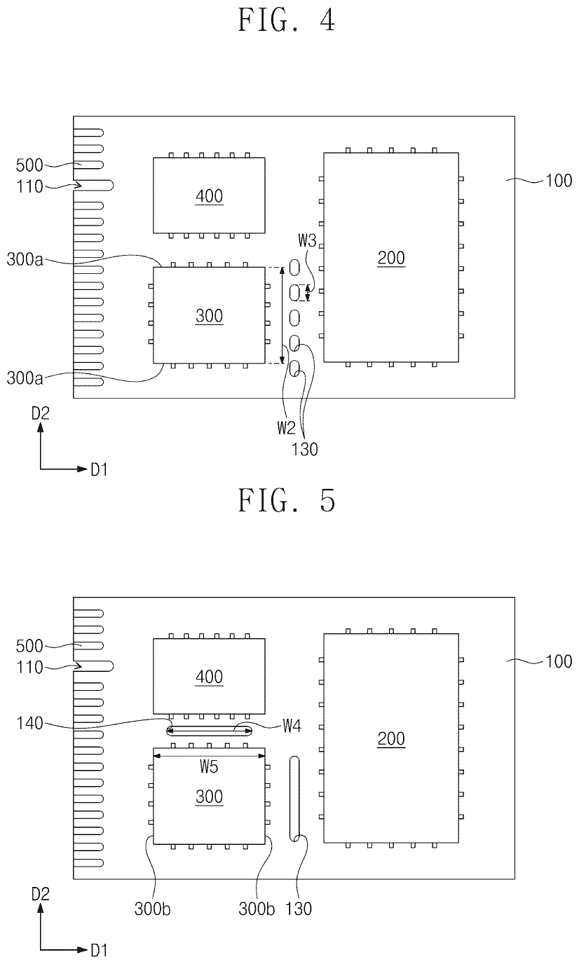

FIG. 4 illustrates a plan view showing an example semiconductor module.

Referring to FIG. 4, the first through hole 130 may be provided in plural. Each of the first through hole 130 may have a linear shape that extends in the second direction D2. For example, each of the first through holes 130 may have a length W3 along the second direction D2 greater than a width along the first direction D1 of the first through hole 130. The first through holes 130 may be arranged in the second direction D2 between the first heating device 200 and the second heating device 300. The first through holes 130 may be spaced apart from each other in the second direction D2. The length W3 of each of the first through holes 130 may be less than a width along the second direction D2 of the first heating device 200. A sum of the lengths W3 of the first through holes 130 may be less than a width W2 along the second direction D2 of the second heating device 300. The sum of the lengths W3 of the first through holes 130 may be about 0.2 times to about 1.0 times the width W2 of the second heating device 300. For example, the sum of the lengths W3 of the first through holes 130 may be about 0.4 times to about 0.8 times the width W2 of the second heating device 300.

FIG. 5 illustrates a plan view showing an example semiconductor module.

Referring to FIG. 5, the module substrate 100 may further include a second through hole 140. The second through hole 140 may be provided in the module substrate 100. When viewed in plan, the second through hole 140 may be disposed between the second heating device 300 and the third heating device 400. The second through hole 140 may be spaced apart from the second heating device 300 and the third heating device 400. The second through hole 140 may completely extend in the third direction D3 through the module substrate 100. The second through hole 140 may run across between the second heating device 300 and the third heating device 400. For example, the second through hole 140 may have a linear shape that extends in the first direction D1.

According to some implementations the second heating device 300 may emit a thermal energy greater than that of the third heating device 400. The module substrate 100 may be provided with the second through hole 140 between the second heating device 300 and the third heating device 400. Thus, the third heating device 400 may be prevented from receiving heat emitted from the second heating device 300 and from being damaged by the heat. For example, a semiconductor module may increase in thermal stability and operating stability.

When viewed in the second direction D2, the second through hole 140 may be positioned between lateral surfaces 300b in the first direction D1 of the second heating device 300. A length W4 along the first direction D1 of the second through hole 140 may be less than a width W5 along the first direction D1 of the second heating device 300. The length W4 of the second through hole 140 may be about 0.2 times to about 1.0 times the width W5 of the second heating device 300. For example, the length W4 of the second through hole 140 may be about 0.4 times to about 0.8 times the width W2 of the second heating device 300. When the length W4 of the second through hole 140 is less than about 0.2 times the width W5 of the second heating device 300, it may not be possible to effectively block heat transferred from the second heating device 300 to the third heating device 400. When the length W4 of the second through hole 140 is greater than about 1.0 times the width W5 of the second heating device 300, it may be possible to excessively block heat discharged in the second direction D2 from the second heating device 300. Therefore, the heat may accumulate in the second heating device 300, and the second heating device 300 may be damaged by the heat.

The second through hole 140 may have a width in the second direction D2, which width may be similar to the thickness T of the module substrate 100. Alternatively, the width of the second through hole 140 may be greater than the thickness T of the module substrate 100. The second through hole 140 may have an empty inside. For example, the inside of the second through hole 140 may be filled with air.

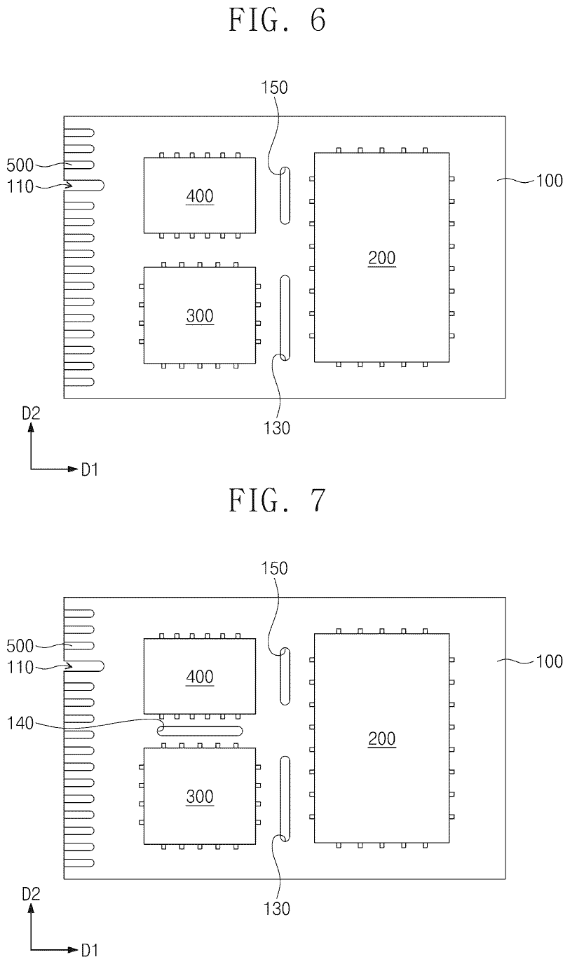

FIG. 6 illustrates a plan view showing an example semiconductor module.

Referring to FIG. 6, the module substrate 100 may further include a third through hole 150. The third through hole 150 may be provided in the module substrate 100. When viewed in plan, the third through hole 150 may be disposed between the first heating device 200 and the third heating device 400. The third through hole 150 may be spaced apart from the first heating device 200 and the third heating device 400. The third through hole 150 may completely extend in the third direction D3 through the module substrate 100. The third through hole 150 may run across between the first heating device 200 and the third heating device 400. For example, the third through hole 150 may have a linear shape that extends in the second direction D2.

According to some implementations the module substrate 100 may be provided with the third through hole 150 between the first heating device 200 and the third heating device 400. The third through hole 150 may run across between the first heating device 200 and the third heating device 400. Therefore, the first heating device 200 and the third heating device 400 may be prevented from being damaged by heat generated therefrom. A semiconductor module may thereby increase in thermal stability and operating stability.

When viewed in the first direction D1, the third through hole 150 may be positioned between lateral surfaces in the second direction D2 of the third heating device 400. A length along the second direction D2 of the third through hole 150 may be less than a width along the second direction D2 of the first heating device 200. The length of the third through hole 150 may be less than a width along the second direction D2 of the third heating device 400.

The third through hole 150 may have a width in the first direction D1, which width may be similar to the thickness T of the module substrate 100. Alternatively, the width of the third through hole 150 may be greater than the thickness T of the module substrate 100. The third through hole 150 may have an empty inside. For example, the inside of the third through hole 150 may be filled with air.

FIG. 7 illustrates a plan view showing an example semiconductor module.

Referring to FIG. 7, the module substrate 100 may include a first through hole 130 discussed with reference to FIG. 2, a second through hole 140 discussed with reference to FIG. 5, and a third through hole 150 discussed with reference to FIG. 6.

According to some implementations the module substrate 100 may be provided with through holes 130, 140, and 150 between the first heating device 200 and the second heating device 300, between the second heating device 300 and the third heating device 400, and between the first heating device 200 and the third heating device 400. The through holes 130, 140, and 150 may block heat exchange among the first heating device 200, the second heating device 300, and the third heating device 400. Therefore, the first heating device 200, the second heating device 300, and the third heating device 400 may be prevented from being damaged by heat generated therefrom. A semiconductor module may thereby increase in thermal stability and operating stability.

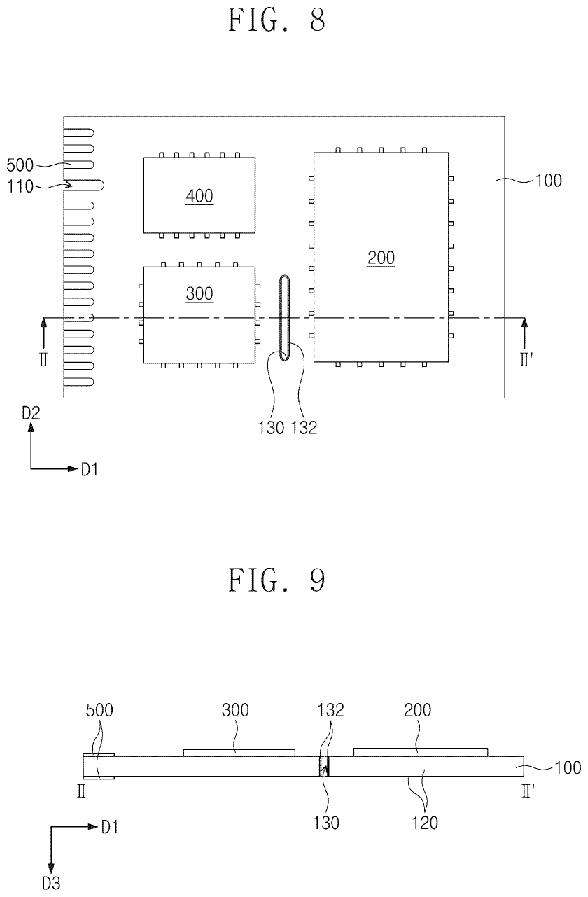

FIG. 8 illustrates a plan view showing an example semiconductor module. FIG. 9 illustrates a cross-sectional view taken along line II-II′ of FIG. 8.

Referring to FIGS. 8 and 9, differently from that shown in FIG. 1, the module substrate 100 may further include a thermal radiation layer 132 disposed in the first through hole 130. For example, the thermal radiation layer 132 may conformally cover an inner wall of the first through hole 130 but may not fill the first through hole 130. The thermal radiation layer 132 may have a ring shape disposed along the inner wall of the first through hole 130. The thermal radiation layer 132 may include a metallic material. The thermal radiation layer 132 may be electrically insulated from the conductive line 120 of the module substrate 100, from the first heating device 200, from the second heating device 300, and from the third heating device 400.

The thermal radiation layer 132 may outwardly discharge a thermal energy of the module substrate 100. The thermal radiation layer 132 may have a thermal conductivity greater than that of the module substrate 100, and thus a thermal energy of the module substrate 100 may be discharged through the thermal radiation layer 132 into the first through hole 130. For example, the thermal radiation layer 132 may absorb heat through conduction from the module substrate 100 and may discharge heat through convection and/or through radiation in the first through hole 130. The thermal radiation layer 132 may outwardly discharge a high thermal energy generated when the first and second heating devices 200 and 200 are operated, and heat exchange may be effectively blocked between the first heating device 200 and the second heating device 300. Accordingly, the first heating device 200 may be prevented from being fractured by the thermal energy.

In addition, a semiconductor module may not include a thermal radiation device, such as a heat sink or a heat spreader, disposed on the first surface 100a or the second surface 100b of the module substrate 100. Accordingly, a semiconductor module may be easily miniaturized and thinned.

According to some embodiments, when the module substrate 100 has a second through hole 140 discussed with reference to FIG. 5 and a third through hole 150 discussed with reference to FIG. 6, at least one additional thermal radiation layer 132 may be provided in one or both of the second through hole 140 and the third through hole 150. For example, the additional thermal radiation layer 132 may conformally cover an inner wall of the second through hole 140 or the third through hole 150 but may not fill the second through hole 140 or the third through hole 150. The additional thermal radiation layer 132 may have a ring shape disposed along the inner wall of the second through hole 140 or the third through hole 150.

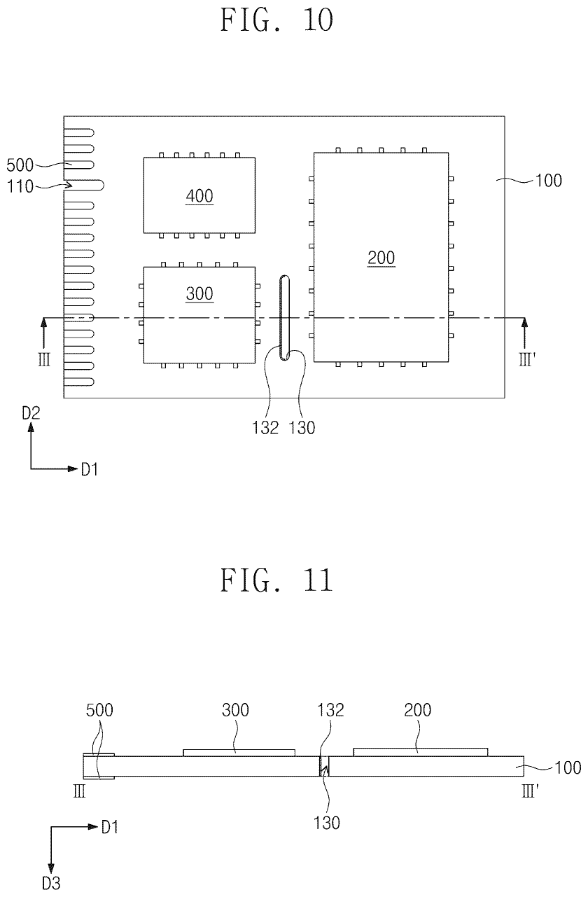

FIG. 10 illustrates a plan view showing an example semiconductor module. FIG. 11 illustrates a cross-sectional view taken along line III-III′ of FIG. 10.

Referring to FIGS. 10 and 11, the inner wall of the first through hole 130 may include a first inner lateral surface adjacent to the second heating device 300 and a second inner lateral surface adjacent to the first heating device 200. The thermal radiation layer 132 may cover the first inner lateral surface and expose the second inner lateral surface. According to some embodiments, heat may be suppressed from being transferred from the first inner lateral surface to the second inner lateral surface of the first through hole 130 through the thermal radiation layer 132 whose thermal conductivity is high. Heat transfer to the first heating device 200 may be minimized. Therefore, it may be possible to increase efficiency at which heat generated from the second heating device 300 is discharged through the thermal radiation layer 132 and also to prevent the first heating device 200 from being damaged due to heat generated from the second heating device 300.

FIG. 12 illustrates a plan view showing an example semiconductor module.

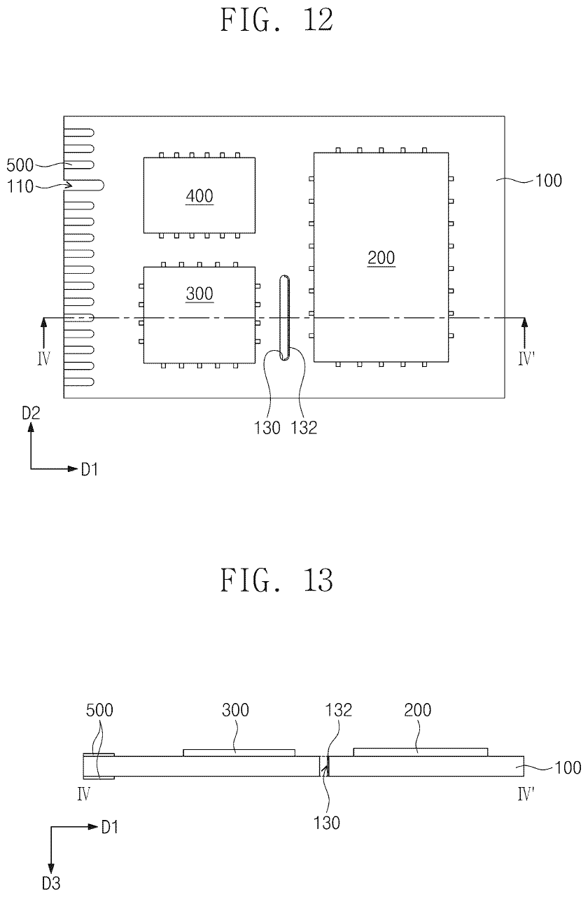

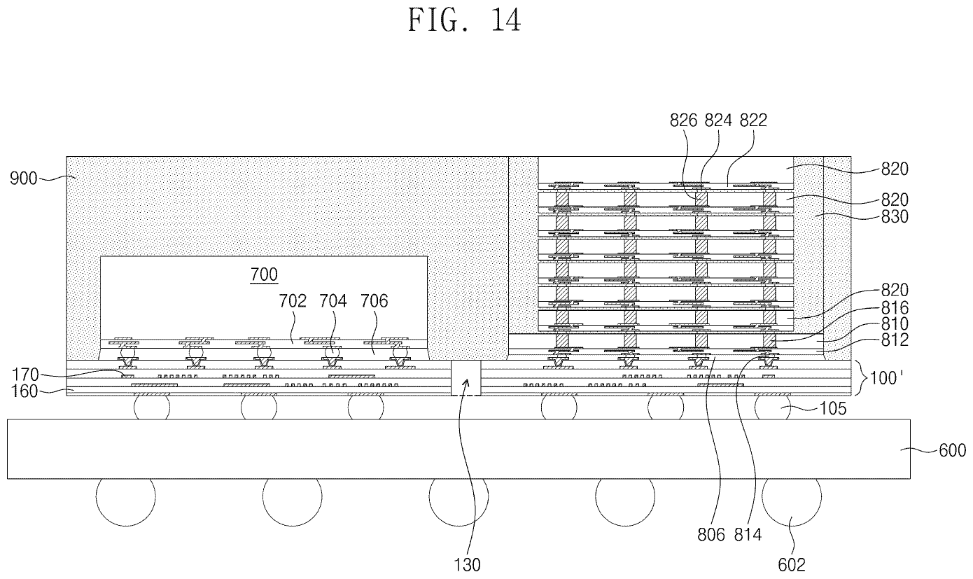

FIG. 13 illustrates a cross-sectional view taken along line IV-IV′ of FIG. 12.

Referring to FIGS. 12 and 13, the inner wall of the first through hole 130 may include a first inner lateral surface adjacent to the second heating device 300 and a second inner lateral surface adjacent to the first heating device 200. The thermal radiation layer 132 may cover the second inner lateral surface and expose the first inner lateral surface. According to some embodiments, as the thermal radiation layer 132 is not provided on the first inner lateral surface of the first through hole 130 adjacent to the second heating device 300, heat may be suppressed from being transferred from the first inner lateral surface to the second inner lateral surface of the first through hole 130. Accordingly, the first heating device 200 may be prevented from being damaged due to heat generated from the second heating device 300.

FIG. 14 illustrates a cross-sectional view showing an example semiconductor package.

Referring to FIG. 14, a package substrate 600 may be provided. The package substrate 600 may include a printed circuit board (PCB) having a signal pattern on a top surface thereof. Alternatively, the package substrate 600 may have a structure in which a dielectric layer and a wiring layer are alternately stacked. The package substrate 600 may have pads disposed on a top surface thereof.

External terminals 602 may be disposed below the package substrate 600. For example, the external terminals 602 may be disposed on terminal pads provided on a bottom surface of the package substrate 600. The external terminals 602 may include solder balls or solder bumps and based on a type and an arrangement of the external terminals 602, a semiconductor package may be provided in the form of one of a ball grid array (BGA) type, a fine ball-grid array (FBGA) type, and a land grid array (LGA) type.

An interposer substrate 100′ may be provided on the package substrate 600. For example, the interposer substrate 100′ may include a substrate protection layer, lower substrate pads in the substrate protection layer, and a plurality of substrate wiring layers stacked on the substrate protection layer.

Each of the substrate wiring layers may include a dielectric pattern 160 and a wiring pattern 170 in the dielectric pattern 160.

The dielectric pattern 160 may cover the substrate protection layer. The wiring pattern 170 may be provided on the dielectric pattern 160. The wiring pattern 170 may provide a wiring or pad portion that horizontally extends on the dielectric pattern 160. The wiring pattern 170 may vertically extend through the dielectric pattern 160 to be coupled to the lower substrate pad or the wiring pattern 170 of another substrate wiring layer positioned beneath the dielectric pattern 160. The dielectric pattern 160 and the wiring pattern 170 may form one substrate wiring layer.

The substrate wiring layers may be stacked on each other. The wiring pattern 170 of an uppermost substrate wiring layer may be provided as upper substrate pads of the interposer substrate 100′.

The interposer substrate 100′ may be mounted on the top surface of the package substrate 600. Substrate terminals 105 may be disposed on a bottom surface of the interposer substrate 100′. The substrate terminals 105 may be provided between package substrate pads of the package substrate 600 and the lower substrate pads of the interposer substrate 100′. The substrate terminals 105 may electrically connect the interposer substrate 100′ to the package substrate 600. For example, the interposer substrate 100′ may be flip-chip mounted on the package substrate 600. The substrate terminals 105 may include solder balls or solder bumps.

A chip stack may be disposed on the interposer substrate 100′. The chip stack may include a base substrate, first semiconductor chips 820 stacked on the base substrate, and a first molding layer 830 that surrounds the first semiconductor chips 820. The following will describe in detail a configuration of the chip stack.

The base substrate may be a base semiconductor chip 810. For example, the base substrate may be a wafer-level semiconductor substrate formed of a semiconductor material such as silicon (Si). In this description below, the base semiconductor chip 810 and the base substrate may indicate the same component and may be allocated with the same reference numeral.

The base semiconductor chip 810 may include a base circuit layer 812 and base through electrodes 816. The base circuit layer 812 may be provided on a bottom surface of the base semiconductor chip 810. The base circuit layer 812 may include an integrated circuit. For example, the base circuit layer 812 may include a memory circuit. The base semiconductor chip 810 may be a memory chip, such as a dynamic random access memory (DRAM), a static random access memory (SRAM), a magnetic random access memory (MRAM), or a Flash memory. The base through electrodes 816 may extend through the base semiconductor chip 810 in a direction perpendicular to a top surface of the interposer substrate 100′. The base through electrodes 816 may be electrically connected to the base circuit layer 812. The bottom surface of the base semiconductor chip 810 may be an active surface. FIG. 14 depicts that the base substrate includes the base semiconductor chip 810, but implementations are not limited thereto. According to some implementations the base substrate may not include the base semiconductor chip 810. For example, the base substrate may be a substrate including no integrated circuit.

The base semiconductor chip 810 may further include a protection layer and first connection terminals 814. The protection layer may be disposed on the bottom surface of the base semiconductor chip 810, thereby covering the base circuit layer 812. The protection layer may include silicon nitride (SiN). The first connection terminals 814 may be provided on the bottom surface of the base semiconductor chip 810. The first connection terminals 814 may be electrically connected to an input/output circuit (e.g., the memory circuit) of the base circuit layer 812. The first connection terminals 814 may be exposed from the protection layer.

The first semiconductor chip 820 may be mounted on the base semiconductor chip 810. For example, the first semiconductor chip 820 and the base semiconductor chip 810 may constitute a chip-on-wafer (COW) structure. The first semiconductor chip 820 may have a width less than that of the base semiconductor chip 810.

The first semiconductor chip 820 may include a first circuit layer 822 and first through electrodes 826. The first circuit layer 822 may include a memory circuit. The first semiconductor chip 820 may be a memory chip, such as dynamic random access memory (DRAM), static random access memory (SRAM), magnetic random access memory (MRAM), or Flash memory. The first circuit layer 822 may include the same circuit as that of the base circuit layer 812, but embodiments are not limited thereto. The first through electrodes 826 may extend through the first semiconductor chip 820 in a direction perpendicular to the top surface of the interposer substrate 100′. The first through electrodes 826 may be electrically connected to the first circuit layer 822. The first semiconductor chip 820 may have a bottom surface or an active surface. The first semiconductor chip 820 may be provided with chip bumps 824 on the bottom surface thereof. The chip bumps 824 may be provided between and electrically connect the base semiconductor chip 810 and the first semiconductor chip 820.

The first semiconductor chip 820 may be provided in plural. For example, a plurality of first semiconductor chips 820 may be stacked on the base semiconductor chip 810. The number of stacked first semiconductor chips 820 may be about 8 to about 32. The chip bumps 824 may be correspondingly provided between the first semiconductor chips 820. In this case, an uppermost first semiconductor chip 820 may not include the first through electrodes 826. In addition, the uppermost first semiconductor chip 820 may have a thickness greater than those of other first semiconductor chips 820 that underlie the uppermost first semiconductor chip 820.

An adhesion layer may be provided between the first semiconductor chips 820. The adhesion layer may include a non-conductive film (NCF). The adhesion layer may be interposed between the chip bumps 824 between the first semiconductor chips 820, thereby preventing the occurrence of electrical short between the chip bumps 824.

The first molding layer 830 may be disposed on a top surface of the base semiconductor chip 810. The first molding layer 830 may cover the base semiconductor chip 810 and surround the first semiconductor chips 820. The first molding layer 830 may have a top surface coplanar with that of the uppermost first semiconductor chip 820, and the uppermost first semiconductor chip 820 may be exposed from the first molding layer 830. The first molding layer 830 may include a dielectric polymer material. For example, the first molding layer 830 may include an epoxy molding compound (EMC).

The chip stack may be mounted on the interposer substrate 100′. For example, the chip stack may be coupled through the first connection terminals 814 of the base semiconductor chip 810 to the upper substrate pads of the interposer substrate 100′. The first connection terminals 814 may be provided between the base circuit layer 812 and the upper substrate pads of the interposer substrate 100′.

A first underfill layer 806 may be provided between the interposer substrate 100′ and the chip stack. The first underfill layer 806 may surround the first connection terminals 814, while filling a space between the interposer substrate 100′ and the base semiconductor chip 810.

A second semiconductor chip 700 may be disposed on the interposer substrate 100′. The second semiconductor chip 700 may be disposed spaced apart from the chip stack. The second semiconductor chip 700 may have a thickness greater than a thickness of each of the first semiconductor chips 820. The second semiconductor chip 700 may include a semiconductor material, such as silicon (Si). The second semiconductor chip 700 may include a second circuit layer 702. The second circuit layer 702 may include a memory circuit. For example, the second semiconductor chip 700 may be a logic chip. A bottom surface of the second semiconductor chip 700 may be an active surface, and a top surface of the second semiconductor chip 700 may be an inactive surface. The second semiconductor chip 700 may be provided with second connection terminals 704 on the bottom surface thereof. The second connection terminals 704 may be electrically connected to an input/output circuit (e.g., the logic circuit) of the second circuit layer 702.

The second semiconductor chip 700 may be mounted on the interposer substrate 100′. For example, the second semiconductor chip 700 may be coupled through the second connection terminals 704 to the upper substrate pads on the interposer substrate 100′. The second connection terminals 704 may be provided between the second circuit layer 702 and the upper substrate pads of the interposer substrate 100′.

A second underfill layer 706 may be provided between the interposer substrate 100′ and the second semiconductor chip 700. The second underfill layer 706 may surround the second connection terminals 704, while filling a space between the interposer substrate 100′ and the second semiconductor chip 700.

The second semiconductor chip 700 may emit a higher thermal energy in the middle of its operating procedure than that of the chip stack or the first semiconductor chips 820.

A through hole 130 may be provided in the interposer substrate 100′. When viewed in plan, the through hole 130 may be disposed between the second semiconductor chip 700 and the chip stack. The through hole 130 may be spaced apart from the second semiconductor chip 700 and the chip stack. The through hole 130 may completely vertically extend through the interposer substrate 100′. The through hole 130 may run across between the second semiconductor chip 700 and the chip stack. For example, the through hole 130 may have a linear shape that runs across between the second semiconductor chip 700 and the chip stack.

According to some implementations the interposer substrate 100′ may be provided with the through hole 130 between the second semiconductor chip 700 and the chip stack. Therefore, heat emitted from the second semiconductor chip 700 may be prevented from being transferred to the first semiconductor chips 820 of the chip stack, and the first semiconductor chips 820 may be prohibited from being damaged due to the heat. Accordingly, a semiconductor package may increase in thermal stability and operating stability.

A second molding layer 900 may be provided on the interposer substrate 100′. The second molding layer 900 may cover the top surface of the interposer substrate 100′. The second molding layer 900 may surround the chip stack and the second semiconductor chip 700. The second molding layer 900 may include a dielectric material. For example, the second molding layer 900 may include an epoxy molding compound (EMC).

In a semiconductor module according to some implementations a controller device may emit a higher thermal energy than that of a memory device. A module substrate may be provided with a through hole between the memory device and the controller device. Thus, heat emitted from the controller device may be prevented from being transferred to the memory device, and the memory device may be prohibited from being damaged due to the heat. Accordingly, the semiconductor module may increase in thermal stability and operating stability.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the present disclosure describes in connection with some implementations illustrated in the accompanying drawings, it will be understood by one of ordinary skill in the art that variations in form and detail may be made therein without departing from the spirit and essential feature of the semiconductor module. The above disclosed embodiments should thus be considered illustrative and not restrictive.

What is claimed is:

1. A semiconductor module comprising:
a module substrate;
a controller device and a memory device mounted on a surface of the module substrate; and
a plurality of tabs at a side of the module substrate,
wherein the module substrate has a first through hole that vertically extends through the module substrate,
wherein the first through hole is between the controller device and the memory device,
wherein the first through hole extends in a first direction that runs across between the controller device and the memory device,
wherein a length of the first through hole along the first direction is less than a width of the controller device along the first direction.

2. The semiconductor module of claim 1, wherein the length of the first through hole is 0.4 times to 0.8 times the width of the controller device.

3. The semiconductor module of claim 1, wherein
the controller device has a lateral surface in a second direction toward the first through hole, and
when viewed in the second direction, the first through hole is between lateral surfaces of the controller device in the first direction.

4. The semiconductor module of claim 1, wherein
the first through hole includes a plurality of first through holes, and
the plurality of first through holes is arranged in the first direction.

5. The semiconductor module of claim 4, wherein a sum of lengths of the first through holes is 0.4 times to 0.8 times the width of the controller device.

6. The semiconductor module of claim 1, further comprising a power device mounted on the surface of the module substrate,
wherein the module substrate has a second through hole that vertically extends through the module substrate,
wherein the second through hole is between the controller device and the power device or between the memory device and the power device.

7. The semiconductor module of claim 6, wherein
the second through hole extends between the controller device and the power device in a direction that runs across between the controller device and the power device, and
wherein a length of the second through hole along a second direction is less than a width of the controller device along the second direction, the second direction running across between the controller device and the power device.

8. The semiconductor module of claim 6, wherein the second through hole extends between the memory device and the power device in a direction that runs across between the memory device and the power device.

9. The semiconductor module of claim 1, wherein
the controller device is spaced apart from the memory device in a second direction that intersects the first direction,
the tabs are spaced apart in the second direction from the controller device, and
the tabs are arranged in the first direction.

10. The semiconductor module of claim 1, wherein
the controller device and the memory device are mounted on a top surface of the module substrate, and
the controller device and the memory device are electrically connected to the tabs through a plurality of lines provided on a bottom surface of the module substrate.

11. A semiconductor module, comprising:
a module substrate;
a controller device, a memory device, and a power device that are spaced apart from each other on a top surface of the module substrate; and
a plurality of tabs on a side of the module substrate in a first direction,
wherein the controller device and the power device are on a side of the memory device in the first direction,
wherein the module substrate has a first through hole and a second through hole that vertically extend through the module substrate,
wherein the first through hole extends in a second direction between the controller device and the memory device, the second direction intersecting the first direction, and
wherein the second through hole is between the controller device and the power device.

12. The semiconductor module of claim 11, wherein a length along the second direction of the first through hole is less than a width along the first direction of the controller device.

13. The semiconductor module of claim 12, wherein the length of the first through hole is 0.4 times to 0.8 times the width of the controller device.

14. The semiconductor module of claim 11, wherein
the first through hole includes a plurality of first through holes, and
the plurality of first through holes is arranged in the second direction.

15. The semiconductor module of claim 11, wherein
the controller device and the power device are spaced apart from each other in the second direction, and
the second through hole extends in the first direction between the controller device and the power device.

16. The semiconductor module of claim 15, wherein a length of the second through hole along the first direction is less than a width of the controller device along the first direction.

17. The semiconductor module of claim 11, wherein the controller device, the memory device, and the power device are electrically connected to the tabs through a plurality of lines provided on a bottom surface of the module substrate.

18. A semiconductor module, comprising:
a substrate;
a first heating device mounted on a top surface of the substrate; and
a second heating device mounted on the top surface of the substrate and spaced apart in a first direction from the first heating device,
wherein the substrate has a through hole between the first heating device and the second heating device, the through hole vertically extending through the substrate,
wherein the through hole extends in a second direction that runs across between the first heating device and the second heating device,
wherein a length along the second direction of the through hole is less than a width along the second direction of the first heating device and a width along the second direction of the second heating device, and
wherein the through hole is filled with air.

19. The semiconductor module of claim 18, wherein, when viewed in the first direction, the through hole is between lateral surfaces in the second direction of the first heating device and between lateral surfaces in the second direction of the second heating device.

20. The semiconductor module of claim 18, wherein
the through hole includes a plurality of through holes, and
the plurality of through holes is arranged in the second direction.
